(19) United States
(12) Patent Application Publication
(10) Pub. No.: US 2009/0097522 A1
(43) Pub. Date: Apr. 16, 2009

(54) VERTICAL CAVITY SURFACE EMITTING LASER DEVICE

(76) Inventors: John Justice, Cork (IE); Brian Corbett, Cork (IE)

Correspondence Address: PATTERSON & SHERIDAN L.L.P. NJ Office, 3040 Oak Post Road, Suite 1500, Houston, TX, 77056-6582, US

(21) Appl. No.: 12/278,114

(22) PCT Filed: Jan. 30, 2007
(86) PCT No.: PCT/EP07/50892

§ 371 Date: Dec. 29, 2008

(30) Foreign Application Priority Data
Feb. 3, 2006 (GB) 0602196.8

(51) Int. Cl. H01S 5/12

(52) U.S. Cl. 372/50.11

(57) ABSTRACT

A vertical cavity surface emitting laser device is provided that comprises a monolithically integrated grating (12) disposed over an output mirror surface of the device, the grating (12) being separate from the output mirror surface and being adapted to provide an on-axis forward diffraction mode at a characteristic wavelength of the device that is suppressed with respect to an off-axis forward diffraction mode at that wavelength, so as to produce a structured, predominantly off-axis, output beam (9) from the device. The grating (12) may be adapted to have a grating depth and refractive index so as to maximise suppression of the on-axis forward diffraction mode. In an alternative scenario, the grating (12) may be adapted to provide an off-axis forward diffraction mode at a characteristic wavelength of the device that is suppressed with respect to an on-axis forward diffraction mode at that wavelength, so as to produce a structured, predominantly on-axis, output beam from the device. The grating (12) may also be adapted to have a grating depth and refractive index so as to minimise the effect of feedback into the cavity due to the presence of the grating. The grating (12) may be patterned with a periodicity greater than the characteristic wavelength of the device. The grating (12) may be formed of a single level or multiple levels of material. The grating may be disposed directly on the output mirror surface. A refractive index of the grating (12) may be intermediate between a refractive index of the output mirror of the device and a refractive index of a likely surrounding medium. Various uses of such a device are also disclosed.

The present invention relates to a vertical cavity surface emitting laser device.

Vertical cavity surface emitting semiconductor lasers (VCSELs) are finding a wide variety of applications due to their small size, their low power consumption and their relatively low cost of manufacture. Such lasers generally emit a circularly symmetric beam, which can have either one or many spatial modes. This beam can be manipulated and shaped as desired for different applications using various separate optical elements such as lenses, beam-splitters, diffractive or holographic structures. An example optical function is the conversion of a single beam into an array of beamlets (optical fan-out) and can be generated by using a VCSEL to illuminate an appropriately-designed diffractive optical element (see M. Ghisoni, J. Bengtsson, J. A. Vukusic, et al., ‘Single- and multimode VCSELs operating with continuous relief kinoform for focussed spot-array generation’, IEEE Photon. Technol. Lett., Vol. 9, pp, 1466-1468 (1997)). These optical elements must be aligned with respect to the VCSEL beam and are generally of a dimension greater than 1 mm. Packaging such a system with the light source and the optical element can therefore be costly. Simpler optical functions such as splitting a laser beam into two beams or the generation of a light beam in the form of a ring are also useful.

Some examples of beam modification on VCSELs have been by way of the integration of a collimating lens structure.

For example, as disclosed in E. M. Strzelecka et al, Proc. LEOS 1996, pp 271-272, a refractive lens has previously been integrated on the surface of a laser.

U.S. Pat. No. 5,838,715 discloses the integration of a lens element onto a VCSEL as a means to shape the internal mode in the laser and to achieve a larger single mode output.

As disclosed in Chr. Gimkiewicz et al., “Wafer-scale replication and testing of micro-optical components for VCSELs,” SPIE Vol. 5433, Micro-Optics, VCSELs, and Photonic Interconnects, Strasbourg, France, April, 2004, a Fresnel lens has previously been formed in a dielectric overlayer on a VCSEL.

As disclosed in H. Martinsson, J. Bengtsson, M. Ghisoni, and A. Larsson, “Monolithic integration of vertical-cavity surface-emitting laser and diffractive optical element for advanced beam shaping,” IEEE Photon. Technol. Lett., vol. 11, pp. 503-505, May 1999, and in M. Karlsson, F. Nikolajeff, J. Vukusic, H. Martinsson, J. Bengtsson, and A. Larsson, “Monolithic integration of continuous-relief diffractive structures with vertical-cavity surface-emitting lasers,” IEEE Photon. Technol. Lett., vol. 15, pp. 359-361, March 2003, an etched grating has previously been formed on the substrate side of a substrate-emitting VCSEL. Interaction of gratings or diffractive optical elements (DOE) and VCSELs are used to achieve complex beam shaping such as converting a single beam into a 4x4 array of beamlets. Such functionality requires that there be a high sampling density of the beam by the DOE, in turn requiring that the beam size be much larger than the grating pitch. Hence a grating is imposed on the substrate side, or a separate DOE is used to shape the beam into the desired pattern.

In the above examples, the distance between the lens surface and the emitting aperture are greater than 50 microns. In another example, disclosed in J. P. Justice, P. Lambkin, M. Meister, R. Winfield, and B. Corbett, “Monolithic Integration of Wavelength-Scale Diffractive Structures on Red Vertical-Cavity Lasers by Focused Ion Beam Etching”. IEEE Photon. Tech. Lett. 16 (8) p 1796, (2004), a grating was etched into the surface of a VCSEL mirror using focused ion beam etching; technical problems have been identified with this approach relating to performance, reliability and optimisability.

It is desirable to improve upon aspects of the above-mentioned systems.

Many applications require that the polarization of VCSELs is stable under all operating conditions. This is not intrinsic to VCSELs emitting between 800 nm and 1100 nm for example and so many techniques are disclosed that select one polarization direction over another. However, in all of these techniques, the objective is to maintain a single output beam.

For example, Ostermann disclose a surface grating etch to achieve this in Photonics Technology Letters, ‘Shallow surface grating for high-power VCSELs with one preferred polarization for all modes’, Vol 17 page 1593 (2005).

Chou et al in Appl. Phys. Lett 67 742 (1994) disclose a sub-wavelength metallic grating to achieve polarization stability.

U.S. Pat. No. 6,002,705 discloses the realisation of adjacent VCSELs with perpendicular polarizations by defining of a grating in a deposited dielectric (silicon nitride) which was treated at a high temperature to deliberately induce stress, and thus to control the polarization of emission from the VCSEL with a beam in the forward direction.

In U.S. Pat. No. 6,785,320 there is disclosed the use a grating to control polarization. The structure substantially comprises a full VCSEL; a single beam is emitted and a waveguide is incorporated.

There are also disclosures (e.g. U.S. Pat. No. 6,055,262 and U.S. Pat. No. 6,191,890) relating specifically to the use of a grating as a reflective mirror in a VCSEL to reduce the number of DBR mirror pairs required, or eliminating the need for any mirror at all.

There are also disclosures relating to the changing of the spectral properties of an incident beam due to waveguiding in a grating. This originates in what are called Woods anomalies discovered in conventional metallic gratings in the early 1900's.

According to a first aspect of the present invention, there is provided a vertical cavity surface emitting laser device comprising a monolithically integrated grating disposed over an output mirror surface of the device, the grating being separate from the output mirror surface and being adapted to produce a structured output beam from the device.

The grating may be adapted to provide an on-axis forward diffraction mode at a characteristic wavelength of the device that is suppressed with respect to an off-axis forward diffraction mode at that wavelength, so as to produce a structured, predominantly off-axis, output beam from the device.

The grating may be adapted to provide at most 25% of the beam's intensity in the on-axis diffraction mode. The grating may be adapted to provide at most 15% of the beam's intensity in the on-axis diffraction mode. The grating may be adapted to provide at most 5% of the beam's intensity in the on-axis diffraction mode. The grating may be adapted to provide at most 2.5% of the beam's intensity in the on-axis diffraction mode.

The grating may be adapted to have a grating depth and refractive index so as to maximise suppression of the on-axis forward diffraction mode.

The grating may be adapted to have a grating depth L and refractive index n₁ determined at least in part in dependence on the following:

$$\frac{2 π {n}_{1} L}{λ} - \frac{2 π {n}_{a} L}{λ} = ( 2 M + 1 ) π ,$$

where λ is the characteristic wavelength of the device, nₐ is a refractive index of a likely surrounding medium, and M is zero or a positive integer, at least for a grating with an equal mark-space.

The grating may be adapted to have a grating depth and refractive index so as to minimise the effect of feedback into the cavity due to the presence of the grating.

The grating may be adapted to have a grating depth L and refractive index n₁ determined at least in part in dependence on the following:

$$L = K \frac{λ}{2 {n}_{1}} ,$$

where λ is the characteristic wavelength of the device and K is a positive integer, at least for a grating with an equal mark-space.

The grating may be adapted to provide an off-axis forward diffraction mode at a characteristic wavelength of the device that is suppressed with respect to an on-axis forward diffraction mode at that wavelength, so as to produce a structured, predominantly on-axis, output beam from the device.

The grating may be adapted to provide at most 30% of the beam's intensity in the off-axis diffraction modes.

The grating may be patterned with a periodicity greater than the characteristic wavelength of the device.

The grating may be patterned with a periodicity greater than the optical wavelength in a likely surrounding medium.

The grating may comprise a single layer of material.

The grating may comprise a plurality of layers of material.

The grating may be formed by deposition and subsequent etching of the at least one layer of material.

At least one layer of the grating may comprise non-metallic material.

At least one layer of the grating may comprise dielectric material.

At least one layer of the grating may comprise semiconductor material.

The grating may be adapted to have substantially no waveguiding function.

The grating is preferably not a waveguide grating.

The grating may be disposed directly on the output mirror surface.

A buffer layer may be provided between the grating and the output mirror surface.

The thickness of the buffer layer is preferably no more than ten times the thickness of the grating layer.

A refractive index of the grating may be intermediate between a refractive index of the output mirror of the device and a refractive index of a likely surrounding medium.

The likely surrounding medium may be air.

The device may comprise material at least partially surrounding the grating that is adapted to provide an anti-resonant or other absorbing function. The material may be disposed over the output mirror surface.

The grating may be a linear grating. The grating may be a two-dimensional grid grating. The grating may be a circular grating.

The grating may be adapted to produce a structured beam having at least one ring-like off-axis lobe.

The grating may be adapted to produce a structured beam having a plurality of lobes.

The grating may be adapted to produce an output beam having two off-axis lobes.

The grating may be adapted to produce a structured output beam having four off-axis lobes.

The grating may be adapted to produce a structured beam having a plurality of off-axis lobes.

The plurality of lobes may comprise an on-axis lobe associated with the on-axis forward diffraction mode.

The device may comprise a surface having a relief that is adapted to induce mode control. The surface relief may be adapted to provide an output beam comprising lobes each being or comprising or relating to substantially a single mode. The surface relief may comprise an etched surface relief. The grating may be disposed over at least part of the surface relief.

According to a second aspect of the present invention, there is provided a method of making a device according to the first aspect of the present invention, comprising depositing at least one layer of material over the output mirror surface of the device and patterning the at least one layer to form the grating.

According to a third aspect of the present invention, there is provided a method of fine tuning suppression of the on-axis diffraction mode of a device described above in which the grating is adapted to provide an on-axis forward diffraction mode at a characteristic wavelength of the device that is suppressed with respect to an off-axis forward diffraction mode at that wavelength, comprising operating the device on-wafer and controlling the etching or equivalent processing of at least one layer of material that forms the grating until a suitable suppression is achieved.

According to a fourth aspect of the present invention, there is provided an apparatus having an array of devices according to the first aspect of the present invention.

According to a fifth aspect of the present invention, there is provided a use of a device according to the first aspect of the present invention to determine a change in optical path length, comprising subjecting the light of at least one lobe to the change in optical path length, bringing the light of the at least one lobe back together with the light of at least one other lobe not subject to the change in optical path length to form interference fringes, and determining the change in optical path length from the interference fringes.

According to a sixth aspect of the present invention, there is provided a use of a device according to the first aspect of the present invention in which at least one of the lobes is used to monitor an output power in at least one of the other lobes.

According to a seventh aspect of the present invention, there is provided a use of a device according to the first aspect of the present invention in which at least one of the lobes is used to monitor a temporal state of the device.

According to an eighth aspect of the present invention, there is provided a use of a device according to the first aspect of the present invention in which at least one of the lobes is used to monitor a spectral state of the device.

According to a ninth aspect of the present invention, there is provided a use of a device according to the first aspect of the present invention in which at least one of the lobes is used to monitor a polarisation state of the device.

According to a tenth aspect of the present invention, there is provided a use of a device according to the first aspect of the present invention in which at least one of the lobes is used to transmit information to a remote location concerning an interaction between an object with light of at least one of the other lobes. Such a device may be used to sense and monitor motion of the object.

According to an eleventh aspect of the present invention, there is provided a use of a device according to the first aspect of the present invention as a directional detector.

According to a twelfth aspect of the present invention, there is provided a use of a device according to the first aspect of the present invention in which detection, reflection or scattering of light from the ring-like lobe at or from an object is used to position that object.

Reference will now be made, by way of example, to the accompanying drawings, in which:

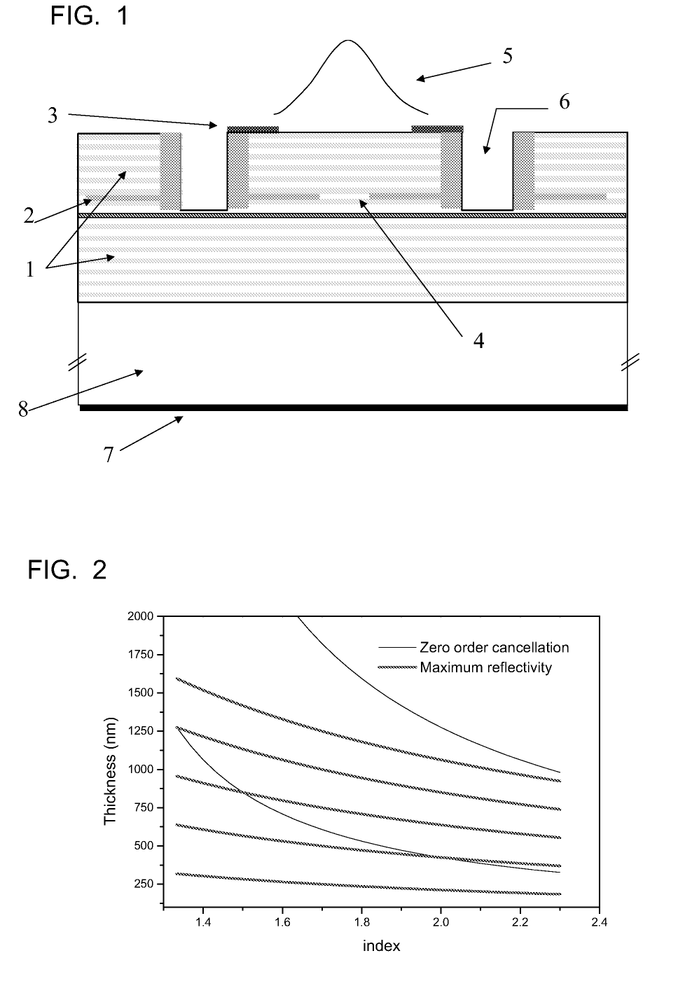

FIG. 1 is a schematic cross-section of a known oxide aperture vertical cavity surface emitting laser (VCSEL);

FIG. 2 is a graph showing layer thickness required for maximum zero-order cancellation and for maximum reflectivity back into the VCSEL cavity as a function of refractive index;

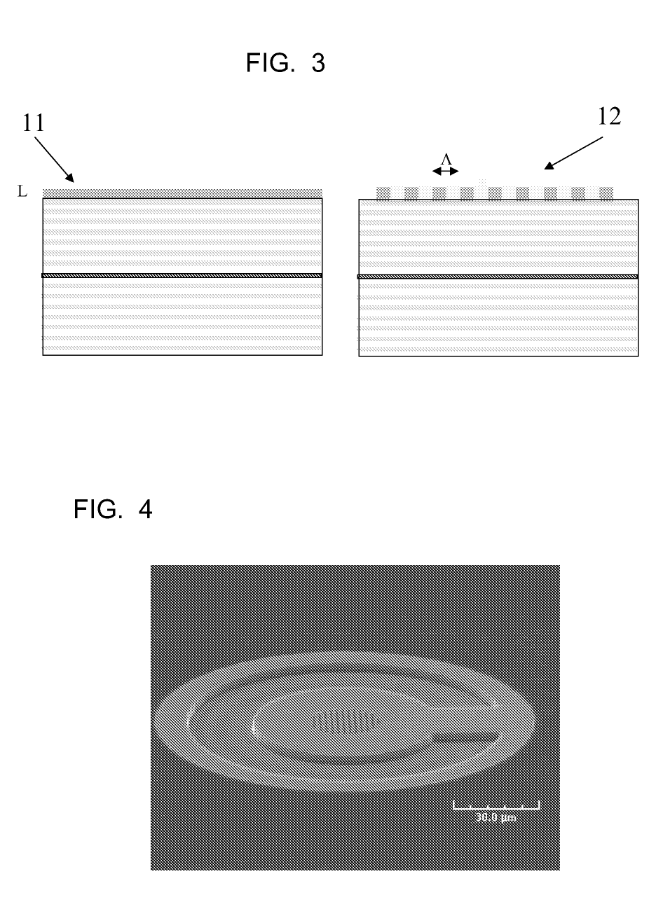

FIG. 3 is a schematic cross-section of a VCSEL with a deposited dielectric layer which is structured into a grating;

FIG. 4 is a scanning electron microscope picture of VCSEL with integrated grating following mesa etch and oxidation and prior to metallization;

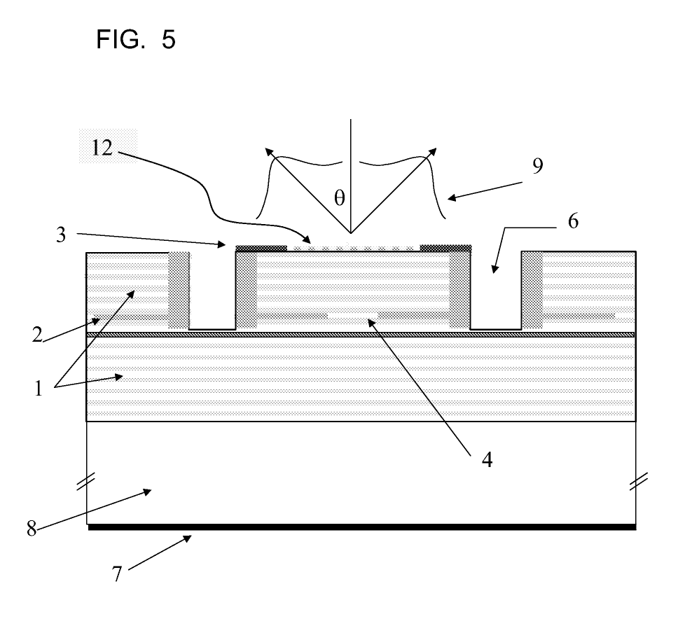

FIG. 5 is a schematic diagram showing a VCSEL according to an embodiment of the present invention;

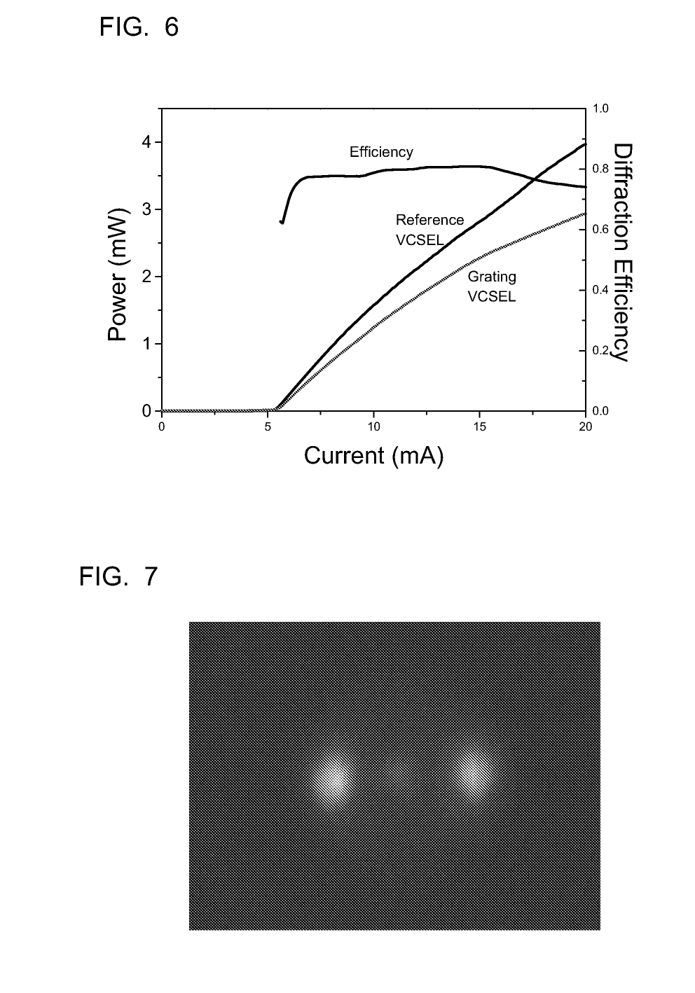

FIG. 6 is a plot showing Light-Current characteristics of a VCSEL with a linear grating;

FIG. 7 shows far field from a VCSEL patterned with dielectric grating.

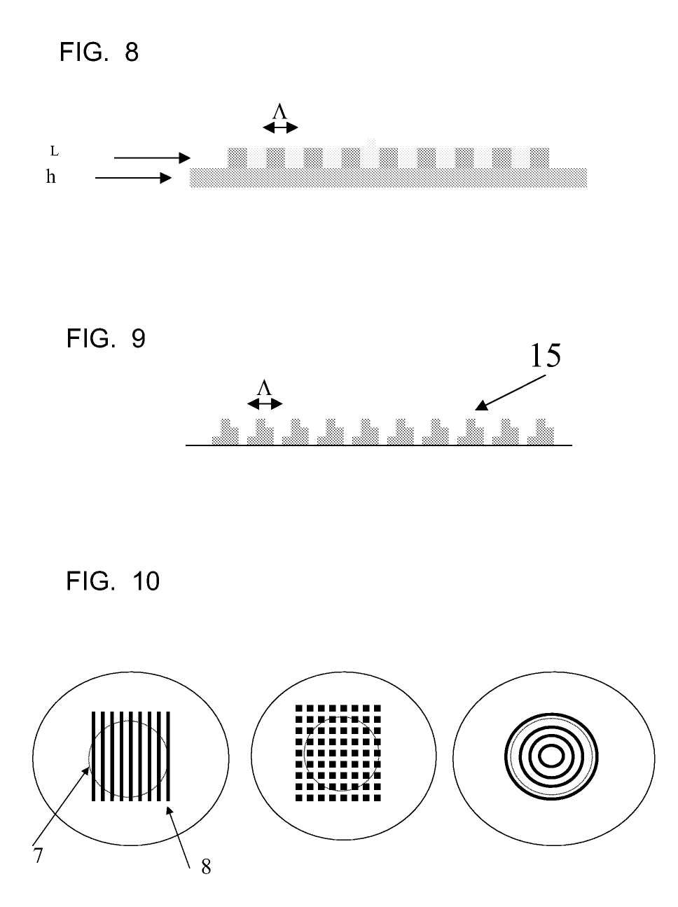

FIG. 8 is a schematic diagram of a grating which consists of a layer of thickness h+L and is etched to a depth L and patterned to realise the desired beam;

FIG. 9 is a schematic diagram of a multilevel grating;

FIG. 10 is a plan view of VCSEL showing different grating patterns that result in different beam structuring;

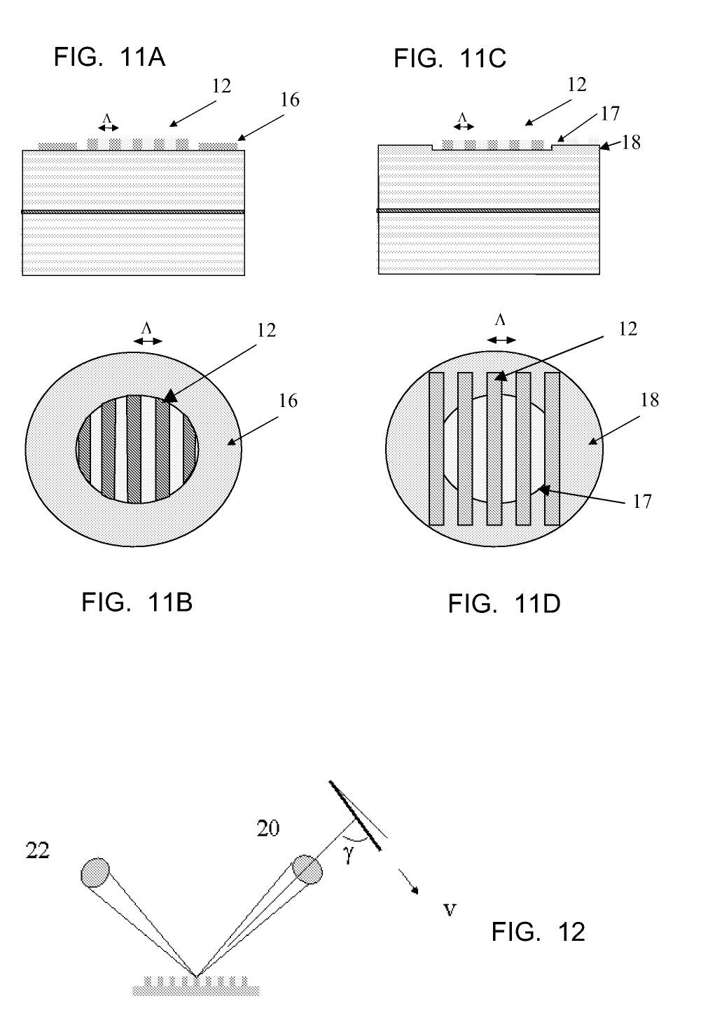

FIG. 11A is a schematic cross-section of a first example of a VCSEL with control of the internal modes, with a deposited dielectric layer which is structured into a grating with thickness for cancellation of the zero order in the centre and a uniform layer of thickness for minimum reflectivity outside, and containing an integrated grating for beam control;

FIG. 11B a schematic plan view of the VCSEL of FIG. 11A;

FIG. 11C is a schematic cross-section of a second example of a VCSEL with control of the internal modes, with an etched surface relief for enhancement of the mirror reflectivity in that region, and containing an integrated grating for beam control;

FIG. 11D is a schematic plan view of the VCSEL of FIG. 11C;

FIG. 12 is a schematic diagram of an arrangement where feedback from a moving object through one of the emitting beams modulates the VCSEL; and

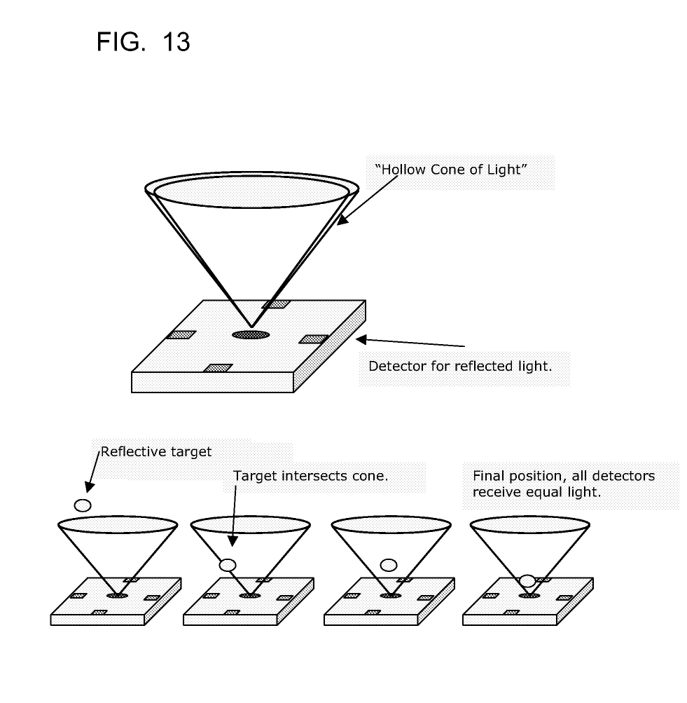

FIG. 13 shows a VCSEL with circular grating emitting a hollow cone of light and a method by which the device can be used to locate an object.

It has been determined by the applicants that various technical problems are associated with the above-mentioned approaches to forming a structured beam from a VCSEL; some of these problems are set out above. In particular, it has been determined by the applicants that the approach described in the J. P. Justice et al disclosure suffers from a problem that the reflectivity of the mirror is reduced by the etching of the mirror surface, thereby adversely affecting the threshold and slope efficiency of the device, thereby adversely affecting the power and efficiency. In addition, the etching exposes semiconductor layers with high Aluminium content which may suffer degradation over time due to, for example, oxidation, thereby adversely affecting the reliability.

The applicants have determined the need to provide a reliable and relatively simple solution that simplifies the optics and the cost associated with packaging such a light system, one that does not require the cost of an alignment between light source and beam shaping element. It has been determined that there is a need to integrate the optical element in a manner which does not adversely affect the reliability of the device and which can be manufactured in a straightforward manner with consequent commercial benefit.

Using an embodiment of the present invention, which will be described in more detail below, it is demonstrated how to control the output beam of a surface emitting cavity device in a manner that is both efficient and will not affect the device lifetime. This is achieved in one embodiment of the present invention by integrating a grating structure formed of a substantially non-absorbing, non-metallic layer on the surface of a VCSEL during the VCSEL manufacturing process, separate or distinct from an output mirror surface of the VCSEL. Substantially non-absorbing can for example be achieved by use of a relatively wide bandgap (and relatively low refractive index). In one embodiment, the layer has a refractive index that has a value between that of the uppermost layer of the mirror and the surrounding medium (e.g. air). The layer can be structured into a grating using lithography and etching techniques. The pitch or periodicity, A, of the grating is preferably greater than the optical wavelength of the emission in the exiting material, thus permitting definition of the grating using conventional optical lithography steps. The grating is such that the other electro-optic characteristics of the device are not substantially degraded and in some cases are improved.

A non-absorbing, non-waveguiding layer can be deposited on the output surface of the mirror using epitaxial growth techniques such as metal-organic Chemical Vapour Deposition (MOCVD) or Molecular Beam Epitaxy, evaporation, sputtering, Plasma Enhanced Chemical Vapour Deposition (CVD), or spin-on techniques techniques. These techniques would be generally known to the skilled person. The material in the layer can consist of SiO, SiNₓ, SiNₓO_{y}, HfOₓ, TiO, AlₓO_{y}, GaP, InGaP, AlGaInP, AlGaAs, InGaN, InGaAsP or other materials known in the art to be mostly transparent at the desired operating wavelength. A sequence of layers can be deposited with benefit especially if the uppermost layer has a large etch selectivity over the underlying layer. It will also be appreciated that the grating can be formed using lift-off techniques.

An embodiment of the present invention provides for a single VCSEL manufactured using generally known processes. In one embodiment a linear grating is structured, resulting in the output being split into two beams with diffraction angles, +/−θ, as may be calculated from the following expression:

Nλ=Λ Sin θ,

where Λ is the pitch of the grating (which is preferably greater than the optical wavelength), N is an integer, and λ is the operating or characteristic emission wavelength of the device.

In another embodiment, a two-dimensional grating can result in four-way beam splitting.

In yet another embodiment, a circular grating can be used to generate a beam with several of the properties of Bessel beam where the light is quasi-collimated adjacent to the exit aperture and forms a ring of light at greater distances.

Use of the monolithically integrated grating can also allow the device to act as a directional detector, as set out below.

FIG. 1 is a schematic diagram of a known oxide aperture vertical cavity surface emitting laser (VCSEL) formed using oxidation technology, upon which an embodiment of the present invention can be based. It will be appreciated that the disclosed process can also be implemented on a VCSEL using implantation or other techniques. The VCSEL comprises DBR mirrors 1 formed with alternate layers of conducting semiconductor, with an oxidation front 2 of a layer with high Aluminium content that defines a current aperture 4. The oxidation is initiated after the etching of a trench 6. A metal contact 3 is provided for injecting current into the device. A second contact 7 is provided on the substrate 8. Also shown in FIG. 1 is the cross-section 5 of the mode profile for a single mode output. A typical VCSEL would have an aperture size (mode dimensions) from 3 μm×3 μm to 20 μm×20 μm, but other sizes are possible. The smaller-dimensioned apertures are single mode and have more useful beam properties but lower power.

A specific embodiment of the present invention will be described using the example of a VCSEL that emits two beams (or has two lobes). In this embodiment, a deposited layer of dielectric is patterned in a series of ridges on the output mirror of the VCSEL and the emission angles are dictated by the periodicity of the patterned structure.

FIG. 5 is a schematic diagram showing a VCSEL according to an embodiment of the present invention. A monolithically integrated grating 12 is provided on, and separate to, an output surface of the device. In this example, the grating 12 is adapted such that the output light of the VCSEL is emitted in two beams propagating at an angle θ with respect to the optical axis of the system, for example using a linear grating.

A VCSEL layer structure can be formed using epitaxial techniques where a first Bragg reflector is grown, an optical cavity with at least one quantum well and a second Bragg reflector. The mirrors can be doped as n and p type with the junction around the quantum well(s). For material systems based on GaAs substrates, the laser can be manufactured using selective oxidation of a buried AlGaAs layer with a high aluminium content or by using implantation techniques that would be generally known to the skilled person.

By integrating a grating within the emitting aperture and on the front mirror surface of a conventional VCSEL, the emission can be changed from a beam substantially propagating along the forward direction to one propagating at an angle, and this beam can be structured by the grating. In this embodiment, a dielectric layer is disposed on the surface and patterned and etched to form a grating.

The grating is adapted to provide an on-axis forward diffraction mode, at the characteristic emission wavelength of the device, that is suppressed with respect to an off-axis forward diffraction mode at that wavelength, so as to produce the structured output beam. It should be noted that the off-axis beams in an embodiment of the present invention are replicas of each other and unlike the far-field from a multi-moded VCSEL which can often have a multi-lobed or annular far field. The two beams are referenced (coherent) to each other.

For the suppression of the zero order diffraction, the optical phase from the etched and non-etched regions should tend to cancel. For an equal mark-space ratio and a single layer of refractive index n₁ in an ambient of refractive index nₐ the etch depth, L, should theoretically be:

$$\frac{2 π {n}_{1} L}{λ} - \frac{2 π {n}_{a} L}{λ} = ( 2 M + 1 ) π ,$$

where M is zero or a positive integer and λ is the characteristic emission wavelength of the device. It will be appreciated that it is not essential to etch the layer completely, provided that the above condition is satisfied or approached, depending on the degree of zero order suppression that is required or tolerated. It will also be appreciated that a sequence of layers may be deposited and structured to obtain an equivalent condition. It will also be appreciated that there may be applications where full, substantial or even part cancellation of the zero order is not desirable, and this is described in more detail below. It will also be appreciated that an equivalent expression can easily be derived be derived and employed by the skilled person for non-equal mark-space ratios, and variation of the mark-space ratio of the grating will change the optimum thickness for zero order cancellation. All these possibilities are within the scope of the present invention.

It is known that the output surface of a typical VCSEL provides a high reflectivity contribution to the overall mirror reflectivity due to the large discontinuity in refractive index between the semiconductor and air at this interface. It is known that making the phase of this reflection anti-resonant to the reflections from the multiplicity of interfaces in the DBR can be used to prevent lasing under certain conditions. This anti-resonant effect can be achieved by making the final layer of a conventional VCSEL structure, which has a refractive index, n, thicker by an odd multiple of λ/4n. In conjunction with etching an aperture in this layer to a depth where the reflection is resonant, this has been used to good effect in stabilizing and controlling the mode properties of VCSELs emitting on-axis.

It will now be realized that the magnitude for reflections from the lower and upper layers of the grating structure back into the VCSEL may not be equal due to the different optical phase introduced by the grating. However, conditions can be found where this phase is matched, which occurs when:

$$L = K \frac{λ}{2 {n}_{1}} ,$$

where K is an integer.

It will be appreciated that choice of L, n₁ and mark-space ratio are the design parameters used to adjust the relative effect of the feedback into the cavity and the zero-order cancellation. FIG. 2 shows the layer thicknesses for which zero-order cancellation occurs and for maximum reflectivity back into the cavity as a function of the refractive index of the layer for a VCSEL emitting at 850 nm; this assumes a single layer with equal mark-space ratio and rectangular profiles. Choosing values of L and n₁ at one of the intersections will provide maximum theoretical reflectivity and maximum zero order suppression; for example L˜850 nm and n₁˜1.5 or L˜425 nm and n₁˜2.

It will be appreciated that other choices of refractive index and of grating layer thickness can be employed with beneficial effect and are included within the scope of this application. For example, a grating layer with modulated but reduced reflectivity will provide structured feedback into the VCSEL cavity and will thus help stabilize the internal mode in a structured form which in turn will be beneficial to intended diffracted output.

It will also be appreciated that the gratings can be introduced onto VCSELs that employ anti-resonant or other absorbing layers to assist in the definition of the spatial mode. Two examples are shown respectively in FIGS. 11A and 11C, with schematic plan views of the two examples being shown respectively in FIGS. 11B and 11D.

In FIGS. 11A and 11B, a layer is structured to provide both mode control and zero-order suppression by etching the dielectric layer to different depths. In addition to the layer being structured in a central portion to form a grating layer 12 to suppress zero order diffraction, as previously described, an outer portion 16 of the layer substantially surrounding the central portion is etched to provide reduced reflection.

As an alternative method of fabrication, and as illustrated in FIGS. 11C and 11D, the VCSEL can be grown with an anti-resonant layer 18, which is then etched back in a central portion (the boundary of the central portion being shown as 17) to make the mirror reflectivity higher where the mode is desired. Etch stop layers, as known in the art, can be employed to control this thickness. The anti-resonant layer is the final layer in the VCSEL structure, which is grown an extra quarter wavelength thick compared with a conventional VCSEL structure. The anti-resonant layer can actually comprise of a sequence of layers including an etch stop, provided the extra thickness is an optical quarter wave (or ¾, 5/4 . . . etc) thicker than the conventional structure. Following the anti-resonant layer, a grating 12 structured to suppress the zero order diffraction can be fabricated as previously described. With such a method, the material that forms the anti-resonant layer can be a different material to that used to form the grating. For example, the anti-resonant layer could comprise a semiconductor material while the grating layer could comprise a dielectric material.

Thus the VCSEL can also be formed with a single spatial mode, where the mode control is induced by an etched surface relief and which has a dielectric grating disposed on the etched surface to yield a VCSEL with output lobes each being a single mode.

If a refractive index is required that is difficult to achieve using a suitable material, multiple layers can be used for the grating as set out below, thereby enabling any effective refractive index to be provided and fine-tuned during the manufacturing process.

During the manufacture of the VCSEL of this embodiment, a layer of Silicon Nitride (SiN) of the desired thickness for suppression of the zero-order reflectivity is deposited on the mirror using plasma enhanced chemical vapour deposition (PECVD). FIG. 3 is a schematic cross-section of a VCSEL with a deposited dielectric layer 11 of thickness L which is then structured (right-hand diagram) into a grating 12 with pitch Λ. Linear gratings are defined in a resist layer using a mask in contact with the resist and exposure to UV light in a standard optical lithography tool. The chips are processed to ensure the best contact between the mask and the resist-covered wafer. Using the resist as a mask, the grating is transferred into the SiN layer using Inductively Coupled Plasma (ICP) dry etching using a CF₄ based gas mixture. After grating formation, conventional VCSEL processing continues with etching of a mesa, selective oxidation of a buried layer to form a current aperture and a waveguide, depositing a Silicon Dioxide (SiO₂) passivation layer on the mesa sidewalls, metal contacting and annealing. FIG. 4 is a scanning electron microscope picture of VCSEL with integrated grating following mesa etch and oxidation and prior to metallization.

In the last stages of processing, the SiO₂ passivation layer is removed from the grating using Buffered Oxide Etch (BOE 1:5). The selectivity of the etch for Silicon Oxide over the Silicon Nitride is 10:1, with etch rates of 6 nm/sec and 0.56 nm/sec respectively. It is preferable to remove this oxide to ensure the correct optical phase for zero order cancellation and maximum diffraction efficiency.

It will be appreciated that there are alternative means of manufacturing an equivalent structure that will be known to those skilled in the art and these known methods can also be employed to make an embodiment of the present invention. For example lift-off of the grating layer can be employed while a different etch procedure might be employed if the grating is formed in a semiconductor grating layer. It will also be appreciated that, although the grating 12 is described above as being formed directly on the mirror surface, this is not essential; a buffer layer can be provided between the grating and the mirror surface.

Light-current (L-I) measurements were recorded from a control VCSEL and from adjacent beam-split VCSELs of the same oxide aperture. FIG. 6 is a plot showing L-I characteristics of a VCSEL with a linear grating showing ˜80% diffraction efficiency into the 1^{st} order emissions. The output power from the two 1^{st} order diffracted beams was measured and the diffraction efficiency calculated. Typical diffraction efficiencies are in the 75-80% range.

The far-field from the VCSEL was also measured. At low currents the device emits in a single spatial mode emission, as shown in FIG. 7 which is the far field from a VCSEL patterned with dielectric grating. The emission angles of +/−25° is as expected from the diffraction of a plane wave from a grating. At higher currents this VCSEL emits in a multimode pattern in the two lobes. An added benefit of this 850 nm wavelength device is that improved stabilisation of the polarisation is obtained. It will be appreciated that this technique can be applied to VCSELs independent of the emitting wavelength.

The desired optical phase pattern can be realized with a single layer with controlled thickness and which is appropriately patterned. It can also be realized by a thicker layer which is partially etched. FIG. 8 is a schematic diagram of a grating which consists of a layer of thickness h+L and is etched to a depth L and patterned to realise the desired beam. The choice of the unetched layer composition and thickness is chosen according to its influence on the VSCEL and the etch selectivity. It can also be realized as a sequence of layers where etching selectivity between the layers can be used to advantage. The optical phase can also be controlled by forming a multilevel or continuous relief grating structure. FIG. 9 is a schematic diagram of a multilevel grating; in the limit the grating can have a continuous profile.

Different patterning and structuring of the dielectric layer(s) will lead to different output beam patterns. FIG. 10 is a plan view of VCSEL showing oxide aperture 7 and different grating patterns resulting in respectively a two-way split beam, a four-way split beam and a focussing/ring like beam. For example a two-dimensional grid structure will lead to a four-way beam splitting while a circular pattern will lead to a quasi Bessel beam with a focusing effect above the source and a diverging ring pattern further from the source. Multilevel structuring and continuous relief can be used for improved beam structuring at the expense of a more complex manufacturing procedure.

Where multiple layers of different refractive index are used, an “effective” or overall refractive index can be considered (as in the case of the multiple DBR mirror layers of the laser device). The term “refractive index” used herein is intended to cover either the actual or the effective refractive index, whichever is appropriate in the circumstance. Typical refractive indices for semiconductor DBR mirrors vary between 3.0 and 3.5, although the mirror can be realised with a dielectric DBR with indices between 1.3 and 2.2. The DBRs normally have the high index layer as the outermost layer.

During the fabrication process described above, the grating can be fine-tuned to get the desired level of zero order cancellation by operating the device on-wafer and controlling the etch step or steps. Such a fine-tuning approach would also work if a semiconductor grating layer were used; in that case a large selectivity between the grating layer which is being finely etched and the underlying layer can be arranged in some circumstances. Such a fine-tuning approach would not be possible with the scheme disclosed in the above-mentioned J. P. Justice et al disclosure.

The grating pitch in an embodiment of the present invention will generally be greater than the wavelength of the emitted light, which itself would typically be between 600 nm (red) and 1600 nm. For a device emitting at a characteristic wavelength of 850 nm the grating pitch could be, for example, between 0.88 and 5 μm. There is limited sampling of the beam, which makes the beam shaping more difficult, but nevertheless this is reasonably straightforward to achieve.

The choice of the refractive index of the grating layer should have an influence on the modal structure of the VCSEL. In addition to polarisation control, it is desirable to increase the fundamental mode power on axis. The etch depth to manipulate the mode reflectivity is a quarter wave which is in the range of 50 nm for a semiconductor layer compared with an etch depth of around 170 nm if one wants to achieve zero-order cancellation. Polarisation stability is a property of the material for red VCSELs which are based upon GaAs/AlGaInP, while it is not defined for other materials and wavelengths such as between 720 nm and 1300 nm unless some intervention is made. Otherwise polarisation switching occurs as the device is driven at different currents. For laser Doppler velocimetry it is beneficial to have polarisation instability but not for other applications.

These devices can be used in sensors. For example an interferometric sensor for measurement of distance or refractive index change can be realized with a two-beam or four-beam VCSEL by recombining the beams, where one beam acts as a reference and the second or other probes the distance of interest.

These VCSELs with off-axis emission allow a range of new applications. For example an optical monitor is envisaged which can be based on a two-way beam splitting device. It is known that feedback into a laser results in instabilities in the laser that are dependent on the nature and strength of the feedback. For example, a frequency dependent feedback leads to a modulation of the diode at the Doppler frequency (f_{D}=2v cos γ/λ in FIG. 12) and this effect has been used to measure movement by laser Doppler velocimetry (LDV). The self-mixing effect has previously been used in conjunction with edge emitting lasers where the output from the back facet is convenient for monitoring the laser response. The situation is more complicated if the laser is a VCSEL because integrating a detector with a VCSEL requires the growth of additional layers, thus increasing the cost of the device.

Using a VCSEL with two output beams, one of the beams can be exposed to a frequency dependent feedback in order to induce a frequency modulation of the VCSEL output while the second beam can be used to detect the light and monitor the feedback more conveniently than in the situation where a photodetector which is grown below the structure. FIG. 12 is a schematic diagram of an arrangement where feedback from an object moving at velocity v at an angle γ through one of the emitting beams 20 modulates the VCSEL at the Doppler frequency f_{D}=2v cos γ/λ. A detector on the other arm 22 can be used to monitor the disturbance.

Similarly the second arm can be used to transmit the information regarding the motion to a distant location.

The second beam can be used as a power monitor for the emission.

In another application, a hollow cone of light emitted by a circular grating may be used like a funnel to help position an object. FIG. 13 shows a VCSEL with circular grating emitting a hollow cone of light (propagating ring) and a method by which the device can be used to locate an object. The object to be positioned is placed at any point within the cone, at a distance from the source. It is then brought towards the source. Once the object intersects the light cone it is detected, either by direct detection at the object (e.g. feedback) or through reflection to detectors near the source. The object position is then corrected, moving it back into the cone. The final position is determined by set values of the reflected/detected light intensities. The target can be a reflective sphere. This system does not require cameras or complex software to precisely align objects. Initial start points may be at any point within the cone of light.

The two beams are generated without additional optics and can be used in alignment situations. Pulsing the laser with result in the two beams pulsing synchronously. The two beams could be coupled to two optical fibres.

The two beams are referenced (coherent) to each other and so when made to overlap with each other they will form interference fringes. The spacing and modulation of these fringes will depend on the optical path difference and so can be used to e.g. measure distance very accurately.

The device will be sensitive to optical feedback in the same manner as other VCSELs. This will allow the device to sense motion and to transmit that signal to a remote location. An optical ‘mouse’ can be made.

Although it is described above that the grating is adapted to provide an on-axis forward diffraction mode, at the characteristic emission wavelength of the device, that is suppressed with respect to an off-axis forward diffraction mode at that wavelength, so as to produce the structured output beam, it will readily be apparent from the above description that the reverse situation is also possible. In other words, the grating may instead be adapted to provide an off-axis forward diffraction mode, at the characteristic emission wavelength of the device, that is suppressed with respect to an on-axis forward diffraction mode at that wavelength, so as to produce the structured output beam. In one example, the grating may be adapted to allow the majority (e.g. greater than 70%) of the beam intensity to be in the on-axis forward diffraction mode and at most, say, 30% to be in the first order diffraction modes, resulting in a VCSEL emitting with three beams.

A “structured output beam” can be understood to mean a collection of lobes or beamlets, for example each travelling at different angles. These lobes can be single moded or multi moded; in the latter case the lobes have internal structure.

As explained above, an approach according to an embodiment of the present invention is to use a monolithically integrated grating to shape the emission from a Vertical Cavity Surface Emitting Laser (VCSEL). This approach offers one or more of the following features and advantages:
A grating can be formed in a deposited layer on the VCSEL output mirror, or at least suitably close to it. With previous approaches the beam has been allowed to expand, for example with a grating in the substrate; this would require a difficult alignment, mounting the device would be less straightforward, and there would inevitably be some absorption in the substrate. Other previous approaches have relied on the etching of a grating into the mirror, resulting in problems with reliability, amongst others.
The grating can be made of a dielectric with a refractive index that is less than the mirror and greater than the surrounding medium, since it is not required to have any of the waveguiding effects that have been used previously in waveguide filters.
The grating pitch can be greater than the optical wavelength, since it is not required to to use subwavelength gratings that have been previously used to stabilize the polarization.
Linear, circular and crossed gratings can be formed.
By selecting the index of the grating material it is possible to change the relative amount of feedback into the laser.
The output beam can consist of a dual beam output, a four-beam output and a conical beam output, for example. In particular, these are not conventional single or multimode beams having a majority of the power close to the forward axis of the system.
Applications can be found in interferometric, motion and position sensors.
A low threshold laser with a structured beam can be produced.
As the grating is integrated with the laser, no alignments are required.
The laser can be fabricated using conventional manufacturing materials and processes with minimal impact on cost. In particular, it does not require specialist techniques such as electron beam lithography.
The process does not significantly affect the power or threshold of the laser.
The grating layer can be designed to help stabilise the polarisation of the laser (if required).
The process does not impact the reliability of the laser.
The process is applicable for all surface emitting lasers (all wavelengths).
New applications are enabled.

1. A vertical cavity surface emitting laser device comprising a monolithically integrated grating disposed over an output mirror surface of the device, the grating being separate from the output mirror surface and being adapted to produce a structured output beam from the device.

2-54. (canceled)

55. A device as claimed in claim 1, wherein the grating is adapted to provide an on-axis forward diffraction mode at a characteristic wavelength of the device that is suppressed with respect to an off-axis forward diffraction mode at that wavelength, for example so as to produce a structured, predominantly off-axis, output beam from the device.

56. A device as claimed in claim 1, wherein the grating is adapted to have a grating depth and refractive index so as to maximise suppression of the on-axis forward diffraction mode.

57. A device as claimed in claim 1, wherein the grating is adapted to have a grating depth L and refractive index n₁ determined at least in part in dependence on the following:
$$\frac{2 π {n}_{1} L}{λ} - \frac{2 π {n}_{a} L}{λ} = ( 2 M + 1 ) π ,$$
where λ is the characteristic wavelength of the device, nₐ is a refractive index of a likely surrounding medium, and M is zero or a positive integer, at least for a grating with an equal mark-space.

58. A device as claimed in claim 1, wherein the grating is adapted to have a grating depth and refractive index so as to minimise the effect of feedback into the cavity due to the presence of the grating, and/or wherein the grating is adapted to have a grating depth L and refractive index n₁ determined at least in part in dependence on the following:
$$L = K \frac{λ}{2 {n}_{1}} ,$$
where λ is the characteristic wavelength of the device and K is a positive integer, at least for a grating with an equal mark-space.

59. A device as claimed in claim 1, wherein the grating is adapted to provide an off-axis forward diffraction mode at a characteristic wavelength of the device that is suppressed with respect to an on-axis forward diffraction mode at that wavelength, for example so as to produce a structured, predominantly on-axis, output beam from the device.

60. A device as claimed in claim 1, wherein the grating is patterned with a periodicity greater than the characteristic wavelength of the device.

61. A device as claimed in claim 1, wherein the grating is formed by deposition and subsequent etching of at least one layer of material.

62. A device as claimed in claim 1, wherein a refractive index of the grating is intermediate between a refractive index of the output mirror of the device and a refractive index of a likely surrounding medium.

63. A device as claimed in claim 1, wherein the grating is adapted to produce a structured beam having at least one ring-like off-axis lobe.

64. A device as claimed in claim 1, wherein the grating is adapted to produce a structured beam having a plurality of lobes.

65. A device as claimed in claim 1, comprising a surface having a relief that is adapted to induce mode control, for example where the grating is disposed over at least part of the surface relief.

66. A method of fine tuning suppression of the on-axis diffraction mode of a device as claimed in claim 55, comprising operating the device on-wafer and controlling the etching or equivalent processing of at least one layer of material that forms the grating until a suitable suppression is achieved.

67. Use of a device as claimed in claim 64 to determine a change in optical path length, comprising subjecting the light of at least one lobe to the change in optical path length, bringing the light of the at least one lobe back together with the light of at least one other lobe not subject to the change in optical path length to form interference fringes, and determining the change in optical path length from the interference fringes.

68. Use of a device as claimed in claim 64 either as a directional detector, or in which at least one of the lobes is used for at least one of: monitoring an output power in at least one of the other lobes; monitoring a temporal state of the device; monitoring a spectral state of the device; monitoring a polarisation state of the device; and transmitting information to a remote location concerning an interaction between an object with light of at least one of the other lobes, for example to sense and monitor motion of the object.

69. Use of a device as claimed in claim 63 either as a directional detector, or in which detection, reflection or scattering of light from the ring-like lobe at or from an object is used to position that object.
